(19) United States
(12) Patent Application Publication
(10) Pub. No.: US 2024/0030092 A1
(43) Pub. Date: Jan. 25, 2024

(54) RADIO FREQUENCY DEVICES INCLUDING RADIO FREQUENCY ABSORBENT FEATURES

(71) Applicant: Infineon Technologies AG, Neubiberg (DE)

(72) Inventors: Tuncay ERDOEL, Unterhaching (DE); Walter HARTNER, Bad Abbach (DE); Pietro BRENNER, Ebersberg (DE); Simon KORNPROBST, Stephanskirchen (DE); Martin MAYER, Nittendorf (DE)

(21) Appl. No.: 18/351,284

(22) Filed: Jul. 12, 2023

(30) Foreign Application Priority Data
Jul. 21, 2022 (DE) 102022118264.9

(51) Int. Cl. H01L 23/373; H01L 23/552; H01L 23/31

(52) U.S. Cl. CPC H01L 23/373; H01L 23/552; H01L 23/3107

(57) ABSTRACT

A device includes a radio frequency chip and a heat sink arranged over the radio frequency chip. The device further includes a layer stack arranged between the radio frequency chip and the heat sink. The layer stack includes a first layer including a first material, a thermal interface material, and a metal layer arranged between the first material and the thermal interface material.

### CROSS REFERENCE TO RELATED APPLICATION

This application claims priority to German Patent Application No. 102022118264.9 filed on Jul. 21, 2022, the content of which is incorporated by reference herein in its entirety.

### TECHNICAL FIELD

The present disclosure relates to radio frequency devices including radio frequency absorbent features. In addition, the present disclosure relates to methods for manufacturing such devices.

### BACKGROUND

In radio frequency applications, such as e.g., radar systems, more and more functions are packed into components with small packages which may result in increased power loss and enhanced interference between radar signal channels. Accordingly, heat may be increased in small areas and higher efforts may be required for preserving signal isolation between the radar signal channels. Manufacturers of radio frequency devices are constantly striving to improve their products. In particular, it may be desirable to provide radio frequency devices with enhanced heat removal and improved isolation between radar signal channels. In this connection, it may further be desirable to provide suitable methods for manufacturing such devices.

### SUMMARY

An aspect of the present disclosure relates to a device. The device includes a radio frequency chip and a heat sink arranged over the radio frequency chip. The device further includes a layer stack arranged between the radio frequency chip and the heat sink. The layer stack includes a first layer including a first material, a thermal interface material, and a metal layer arranged between the first material and the thermal interface material.

An aspect of the present disclosure relates to a device. The device includes a radio frequency chip and a heat sink arranged over the radio frequency chip. The device further includes a radio frequency absorber material arranged between the radio frequency chip and the heat sink. A relative permittivity of the radio frequency absorber material is greater than 3, and a loss tangent of the radio frequency absorber material is greater than 0.2.

An aspect of the present disclosure relates to a device. The device includes a radio frequency chip and a heat sink arranged over the radio frequency chip. The device further includes a mold compound material arranged between the radio frequency chip and the heat sink. A relative permittivity of the mold compound material is greater than 2, a loss tangent of the mold compound material is smaller than 0.1, and a thickness of the mold compound material layer is greater than 0.4 mm.

### BRIEF DESCRIPTION OF THE DRAWINGS

The accompanying drawings are included to provide a further understanding of aspects and are incorporated in and constitute a part of this specification. The drawings illustrate aspects and together with the description serve to explain principles of aspects. Other aspects and many of the intended advantages of aspects will be readily appreciated as they become better understood by reference to the following detailed description. The elements of the drawings are not necessarily to scale relative to each other Like reference signs may designate corresponding similar parts.

FIG. 1 schematically illustrates a cross-sectional side view of a device 100 in accordance with the disclosure.

FIG. 2 schematically illustrates a cross-sectional side view of a device 200 in accordance with the disclosure.

FIG. 3 schematically illustrates a cross-sectional side view of a device 300 in accordance with the disclosure.

FIG. 4 schematically illustrates a cross-sectional side view of a device 400 in accordance with the disclosure.

FIG. 5 schematically illustrates a cross-sectional side view of a device 500 in accordance with the disclosure.

FIG. 6 schematically illustrates a cross-sectional side view of a device 600 in accordance with the disclosure.

FIG. 7 illustrates a flowchart of a method for manufacturing a device in accordance with the disclosure.

FIG. 8 illustrates a flowchart of a method for manufacturing a device in accordance with the disclosure.

FIG. 9 illustrates a flowchart of a method for manufacturing a device in accordance with the disclosure.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

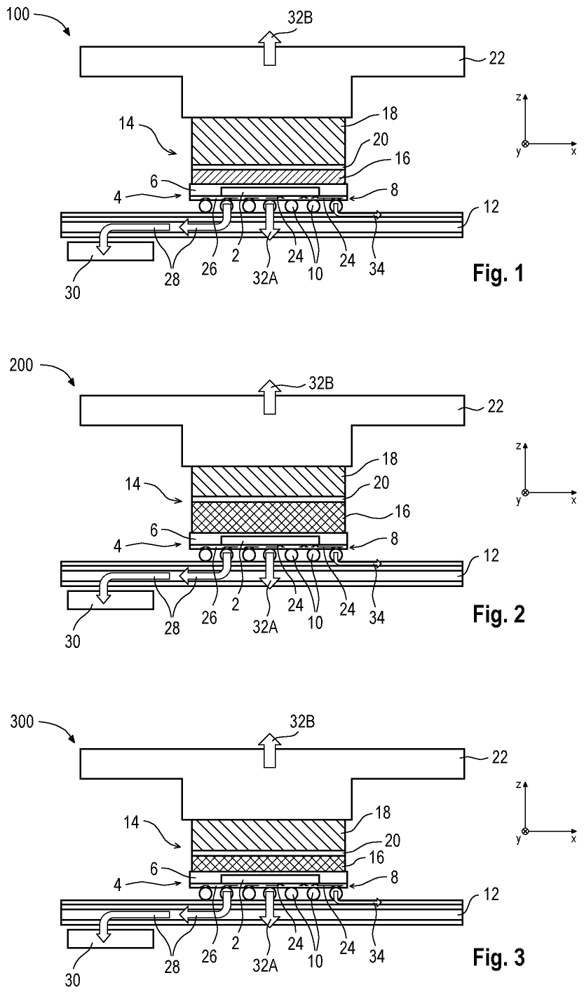

The device 100 of FIG. 1 may include one or multiple semiconductor chips (or semiconductor dies) 2. In the example of FIG. 1, a semiconductor chip 2 may be provided in form of a semiconductor package 4 including an encapsulation material 6 in which the semiconductor chip 2 may be encapsulated. One or multiple electrical redistribution layers 8 may be arranged over the bottom surfaces of the semiconductor chip 2 and the encapsulation material 6. In addition, one or multiple external connection elements 10 may provide a mechanical and electrical connection between the semiconductor package 4 and a printed circuit board 12. The device 100 may include the printed circuit board 12 or not.

The device 100 may further include a layer stack 14 arranged over the semiconductor chip 2, in particular on the top surface of the semiconductor package 4. The layer stack 14 may include a first layer including a first material 16, a thermal interface material 18, and a metal layer 20 arranged between the first material 16 and the thermal interface material 18. Furthermore, a heat sink 22 may be arranged over the layer stack 14, in particular on the top surface of the thermal interface material 18.

The semiconductor chip 2 (or electronic circuits thereof) may operate in a frequency range of greater than about 1 GHz, in some examples greater than about 10 GHz. The semiconductor chip 2 may thus also be referred to as radio frequency chip or high frequency chip or microwave frequency chip in the following. More particular, the radio frequency chip 2 may operate in a radio frequency range or microwave frequency range, which may range from about 1 GHz to about 1 THz, more particular from about 10 GHz to about 300 GHz. Microwave circuits may include, for example, microwave transmitters, microwave receivers, microwave transceivers, microwave sensors, microwave detectors, etc. Devices in accordance with the disclosure may be used for radar applications in which the frequency of the radio frequency signals may be modulated. Accordingly, the radio frequency chip 2 may particularly correspond to a radar chip.

In this regard, it is to be noted that the present disclosure may refer to various electromagnetic or dielectric properties which may be frequency dependent, such as e.g., a relative permittivity (or dielectric constant) εᵣ of a material, a loss tangent tan δ of a material, etc. Values of such electromagnetic properties as provided herein may particularly refer to frequency ranges at which devices in accordance with the disclosure may operate. The given values of the electromagnetic properties may thus particularly be read in connection with the example operating frequencies given above.

Radar microwave devices may e.g., be used in automotive, industrial, military and/or defense applications for range and speed measuring systems. For example, automotive applications may include advanced driver assistant systems, automatic vehicle cruise control systems, vehicle anti-collision systems, etc. Such systems may operate in the microwave frequency range, for example in the 24 GHz, 76 GHz, or 79 GHz frequency bands. In some examples, the use of such systems may provide constant and efficient driving of vehicles. An efficient driving style may, for example, reduce fuel consumption such that CO₂ emission may be reduced and energy savings may be enabled. In addition, abrasion of vehicle tires, brake discs and brake pads may be reduced, thereby reducing fine dust pollution. Improved radar systems, as specified in this description, may thus at least indirectly contribute to green technology solutions, e.g climate-friendly solutions providing an improved mitigation of energy use.

The devices described herein need not be limited to the example technical areas previously mentioned. In further examples, the concepts presented herein may also be implemented for the following RF applications (list not exhaustive): technologies at frequencies beyond 100 GHz, e.g., THz technologies; 5G; 6G; radar-signal based face and gesture recognition sensors; high data transfer communication systems and wireless backhaul systems; body scanning systems for security; medical and health monitoring systems (e.g., medical sensors and data transfer); GBit Automotive Ethernet; high-speed chips for Ethernet, fiber communication and data center switches.

The radio frequency chip 2 of FIG. 1 may be at least partly embedded in the encapsulation material 6. For example, the encapsulation material 6 may include or may be made of at least one of the following materials: mold compound, epoxy, filled epoxy, glass fiber filled epoxy, imide, thermoplast, thermoset polymer, polymer blend, etc. In the example of FIG. 1, the encapsulation material 6 may exemplarily cover the top surface and the side surfaces of the radio frequency chip 2, while the bottom surface of the semiconductor chip 2 may be uncovered by the encapsulation material 6. The bottom surfaces of the encapsulation material 6 and the radio frequency chip 2 may be substantially arranged in a common plane.

The encapsulation material 6 may form a housing (or package) of the radio frequency chip 2. In general, the semiconductor package 4 may be based on any suitable package technology, such as e.g., Flip-Chip BGAs (Ball Grid Arrays), Wirebond-BGAs, eWLB (embedded Wafer Level Ball Grid Arrays), FOWLP (Fan Out Wafer Level Packaging), etc. In the non-limiting example of FIG. 1, the semiconductor package 4 may correspond to a wafer level package, which may be manufactured based on an eWLB (embedded Wafer Level Ball Grid Array) process. It is however to be noted that the semiconductor package 4 is not restricted to a specific package type and may differ in further examples.

The electrical redistribution layer 8 may include one or multiple electrically conductive structures 24 in form of metal layers (or metal tracks), which may extend substantially in parallel to the bottom surfaces of the radio frequency chip 2 and the encapsulation material 6. One or multiple dielectric layers 26 may be arranged between the metal layers 24 in order to electrically isolate the metal layers 24 from each other. Metal layers 24 arranged on different vertical levels may be electrically connected to each other by one or multiple via connections (not illustrated).

The semiconductor package 4 may be mounted on the printed circuit board 12 using the external connection elements 10. Electronic structures of the radio frequency chip 2 may be electrically accessible via the external connection elements 10 and the electrical redistribution layer 8. For example, the external connection elements 10 may include at least one of a solder ball or a solder pillar. In one example, the printed circuit board 12 may include multiple dielectric layers stacked over each other. The dielectric layers may e.g., include or may be made of at least one of a high frequency laminate material, a prepreg material (preimpregnated fiber), or an FR4 material. The printed circuit board 12 may include electrically conductive structures arranged on the bottom surface and/or on the top surface as well as electrically conductive structures arranged inside of the printed circuit board 12.

FIG. 1 exemplarily illustrates various signal paths and thermal paths indicated by arrows. Two arrows on the left indicate an example path 28 for non-radio frequency signals which may be transmitted between the radio frequency chip 2 and a further electronic component 30, such as e.g., a semiconductor chip including logical circuitry. In the non-limiting example of FIG. 1, the electronic component 30 may be arranged on the bottom surface of the printed circuit board 12 such that the non-radio frequency signal path 28 may extend from the top surface of the printed circuit board 12 to the bottom surface of the printed circuit board 12. An arrow in the middle indicates a first example thermal path 32A for heat dissipation in a direction away from the radio frequency chip 2 towards the printed circuit board 12. An arrow at the top indicates a second example thermal path 32B for heat dissipated away from the heat sink 22. A further arrow on the right indicates an example path 34 for radio frequency signals which may be transmitted from the radio frequency chip 2 to one or multiple further components which are not illustrated for the sake of simplicity. In particular, the radio frequency signals may be transmitted via suitable high frequency structures arranged on the top surface of the printed circuit board 12.

In the example of FIG. 1, the first material 16 of the layer stack 14 may include or may be made of a radio frequency absorber material. The radio frequency absorber material may be specified as a material configured to effectively absorb radio signals or radiation in operating frequency ranges of the radio frequency chip 2 as previously specified. Accordingly, the first material 16 may be configured to mitigate crosstalk between multiple radio frequency channels of the radio frequency chip 2 in order to obtain improved radio frequency isolation between the multiple radio frequency channels. In addition, or alternatively, the first material 16 may be configured to mitigate crosstalk between a radio frequency channel of the radio frequency chip 2 and circuitry of a further chip or a further electronic component (not illustrated). In order to provide appropriate crosstalk mitigation, the first material 16 may be particularly arranged adjacent to the radio frequency chip 2. In the non-limiting example of FIG. 1, the bottom surface of the first layer including the first material 16 may be in direct contact with the top surface of the encapsulation material 6.

In the example of FIG. 1, a relative permittivity (or dielectric constant) εᵣ of the first material 16 may be greater than about 5. In a more specific, but non-limiting example, the relative permittivity εᵣ of the first material 16 may be in a range from about 6 to about 7. A loss tangent tan δ of the first material 16 may be greater than about 0.1. In a more specific, but non-limiting example, the loss tangent tan δ may be in a range from about 0.2 to about 0.3. In the example of FIG. 1, the first layer including the first material 16 may have a substantially uniform thickness. In this context, a thickness of the first material 16 may be in a range from about 0.2 mm to about 0.6 mm when measured in the z-direction. In a more specific, but non-limiting example, the thickness of the first material 16 may be in a range from about 0.2 mm to about 0.4 mm.

The first material 16 may include one or multiple of the following radio frequency absorbent materials: carbon, rubber material, conducting polymer, chiral material, a polymer matrix including at least one of conducting particles or magnetic particles.

Carbon may be a radio frequency absorbent material due to its low conductivity. In particular, carbon nanostructures may have suitable properties for radar absorber materials (RAMs). For example, graphite, carbon nanotubes (single or multi-layered), fiber, and carbon black may be used as radio frequency absorbent materials.

Radio frequency absorbent rubber material may include or may correspond to rubber radar absorbing material (RRAM). RRAM composites may be made of rubber as a matrix with electromagnetic wave absorbent materials and may serve as reinforcement. The reinforcements may provide electromagnetic performance of the radar absorbents. In addition, the matrix may provide a soft and flexible body. For example, a reinforcement material of the RRAM may include or may correspond to carbonyl iron. Carbonyl iron may e.g., be applied for microwave absorbent elements as reinforcement in an example frequency range from about 2.6 GHz to about 18 GHz and even higher.

Radio frequency absorbent conducting polymers may be provided in various ways. For example, in a polymer, a formation of polarons and bipolarons may make the polymer conducting. Local oxidation of the polymer may cause such condition, wherein polypyrrole (PPy) may be one non-limiting example.

Chiral materials or (artificial) chiral structures may be specified as materials configured to change a plane of polarization. For electromagnetic waves in chiral materials, the orientation of the spread vector may be in the left direction, while in conventional materials the spread vector may be towards the right. Accordingly, chiral materials may also be referred to as left-handed materials (LHMs) or meta-materials.

Further, radar absorbing materials may be formed by loading an insulating polymer matrix with at least one of conducting particles or magnetic particles. In a more specific example, the polymer matrix may be loaded with conducting filaments or tubules. Here, a length of used filaments may be less than about 0.5 times the wavelength of the median frequency that is to be absorbed.

The metal layer 20 of the layer stack 14 may be arranged on top of the first layer including the first material 16. In the example of FIG. 1, the bottom surface of the metal layer 20 may be in direct contact with the top surface of the first layer including the first material 16. For example, the metal layer 20 may correspond to or may include a metallic foil. As previously described, the first material 16 may be configured to provide electrical performance by mitigating crosstalk between multiple radio frequency channels of the radio frequency chip 2. In this context, the metal layer 20 may be configured to effectively make such electrical performance independent from any additional material arranged above the metal layer 20. This may be achieved by a thickness of the metal layer 20 being greater than two times (or three times) a skin depth of the metal layer 20 at an operating frequency of the radio frequency chip 2. In one specific example, a skin depth of an aluminum layer may be about 300 nm at a frequency of about 77 GHz.

The thermal interface material 18 of the layer stack 14 may be arranged on top of the metal layer 20. In the example of FIG. 1, the bottom surface of the thermal interface material 18 may be in direct contact with the top surface of the metal layer 20. The thermal interface material 18 may be configured to dissipate heat generated by the radio frequency chip 2. In particular, heat may be dissipated via the thermal interface material 18 in a direction from the radio frequency chip 2 towards the heat sink 22 and may thus support cooling of the radio frequency chip 2. In order to provide suitable heat dissipation, the thermal interface material 18 may be particularly arranged adjacent to the heat sink 22.

The thermal interface material 18 may include or may correspond to a silicone matrix with inorganic fillers. The inorganic filler particles may include or may be made from at least one of the following materials: Al₂O₃ (in particular spherical), SiO₂, BN, AN, MgO, ZnO, glass fibers, etc. In the example of FIG. 1, a relative permittivity (or dielectric constant) εᵣ of the thermal interface material 18 may be greater than about 5. A loss tangent tan δ of the thermal interface material 18 may be smaller than about 0.1. In the example of FIG. 1, the thermal interface material 18 may have a substantially uniform thickness. In this context, a thickness of the thermal interface material 18 may be greater than about 0.5 mm when measured in the z-direction.

Dimensions and shapes of the layers included in the layer stack 14 may vary in different examples. In the non-limiting case of FIG. 1, footprints of the first layer including the first material 16, the thermal interface material 18 and the metal layer 20 may be similar when viewed in the z-direction. In further examples, the components of the layer stack 14 may differ with regard to their dimensions in the x-direction and/or y-direction.

The heat sink 22 may include one or multiple metal parts in one example. When measured in the z-direction, a thickness of the metal part(s) may be at least about 1 mm. A surface of the heat sink 22 may not necessarily contact the printed circuit board 12. In particular, no surface of the heat sink 22 may directly contact the printed circuit board 12. In this particular case, the heat sink 22 may not share stress experienced by the semiconductor package 4. In other words, the heat sink 22 may be mechanically decoupled from the printed circuit board 12. In the example of FIG. 1, the heat sink 22 may be fully arranged over the top surface of the radio frequency chip 2. That is, the heat sink 22 may not include parts that can reach down to the printed circuit board 12 and contact the same.

The device 100 of FIG. 1 may provide the following technical effects, in particular compared to conventional devices. The first material 16 of the layer stack 14 may mitigate crosstalk between multiple radio frequency channels of the radio frequency chip 2 as well as crosstalk between a radio frequency channel of the radio frequency chip 2 and other circuitry. As a result, a radio frequency performance of the device 100 may be increased. Furthermore, the thermal interface material 18 and the heat sink 22 may provide thermal paths for efficient dissipation of heat generated by the radio frequency chip 2. As a result, a cooling performance of the device 100 may be enhanced. In sum, the layer stack 14 of FIG. 1 may provide both efficient thermal performance and electrical performance at the same time.

In conventional devices, a metal heat sink arranged on top of a semiconductor package may degrade signal isolation between the multiple radio frequency channels of the radio frequency chip. In contrast to this and in accordance with the disclosure, applying a radio frequency absorber material 16 between the semiconductor package 4 and the heat sink 22 may avoid or at least mitigate such signal isolation degradation caused by the heat sink.

In conventional devices, arranging a heatsink on top of a semiconductor package may not be convenient due to mechanical misalignments and tolerances. In contrast to this and in accordance with the disclosure, the thermal interface material 18 arranged between the semiconductor package 4 and the heat sink 22 may provide mechanical flexibility and may make the arrangement more adjustable against mechanical tolerances. In addition, the thermal interface material 18 may increase a thickness of the layer stack 14, thereby providing a simplified handling of the arrangement.

In the following, further devices in accordance with the disclosure as exemplarily illustrated in FIGS. 2 to 6 are described. Any of these devices may include some or all features of the device 100 of FIG. 1. Accordingly, all comments made in connection with FIG. 1 may also hold true for the examples of FIGS. 2 to 6.

In the device 200 of FIG. 2, the first material 16 may include or may be made of a mold compound material. For example, this mold compound material 16 may include one or multiple of the materials as previously specified in connection with the encapsulation material 6 of FIG. 1. In the example of FIG. 2, the mold compound material 16 may correspond to an overmold material arranged on top of the encapsulation material 6. In further examples, the mold compound material 16 and the encapsulation material 6 may form one single piece. In such cases, the radio frequency chip 2 may be embedded in the mold compound material 16.

In the example of FIG. 2, a relative permittivity (or dielectric constant) εᵣ of the first material 16 may be greater than about 2. A loss tangent tan δ of the first material 16 may be smaller than about 0.1. In the example of FIG. 1, the first layer including the first material 16 may have a substantially uniform thickness. In this context, a thickness of the first material 16 may be in a range from about 0.4 mm to about 0.8 mm when measured in the z-direction. In a more specific, but non-limiting example, the thickness of the first material 16 may be in a range from about 0.5 mm to about 0.7 mm.

The metal layer 20 arranged between the mold compound material 16 and the thermal interface material 18 may be configured to prevent the thermal interface material 18 from reducing a radio frequency performance of the device 200. In this regard, the metal layer 20 may be configured to form a reflector for all parasitic radio frequency wave propagations in the mold compound material 16. In one example, the metal layer 20 may be part of the thermal interface layer 18. In a further example, the metal layer 20 may be deposited on top of the mold compound material 16, for example based on a sputtering technique. In yet a further example, the metal layer 20 may be embedded into the mold compound material 16 during a molding process, such as e.g., a compression molding process.

The device 300 of FIG. 3 may be at least partly similar to the device 200 of FIG. 2. Similarly, the first material 16 may include or may be made of a mold compound material. Compared to FIG. 2, the first layer including the first material 16 may have a reduced thickness when measured in the z-direction. In the example of FIG. 3, the first layer including the first material 16 may have a substantially uniform thickness. In this context, a thickness of the first material 16 may be in a range from about 0.2 mm to about 0.4 mm. A relative permittivity (or dielectric constant) εᵣ of the first material 16 may be greater than about 5. A loss tangent tan δ of the first material 16 may be greater than about 0.2.

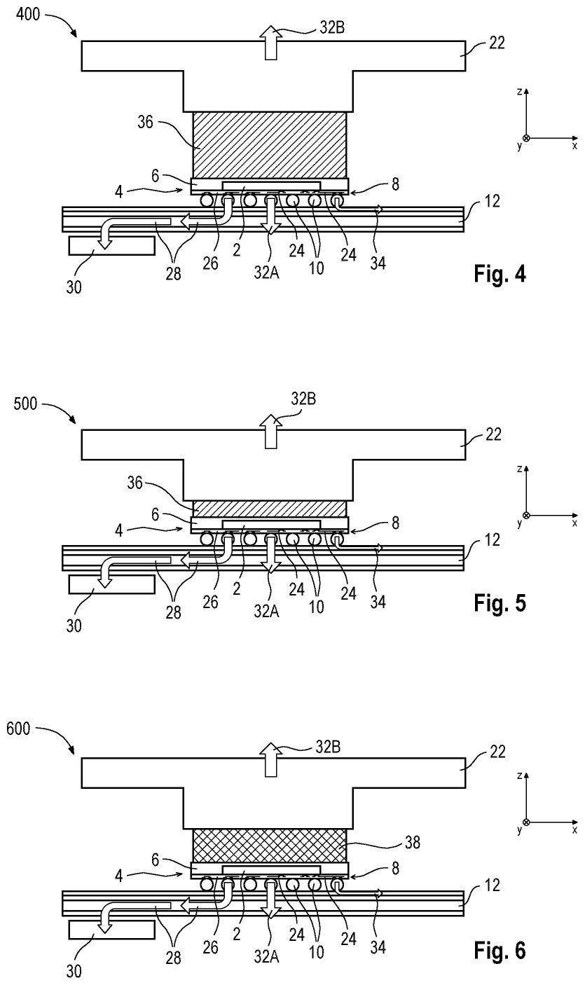

The device 400 of FIG. 4 may be at least partly similar to previously described devices. In the example of FIG. 4, the layer stack 14 of previous examples may be replaced by a radio frequency absorber material 36 arranged between the radio frequency chip 2 and the heat sink 22. In FIG. 4, the radio frequency absorber material 36 may exemplarily be formed as one single layer having a substantially uniform thickness when measured in the z-direction. In this context, a thickness of the radio frequency absorber material 36 may be greater than about 1 mm. The radio frequency absorber material 36 may e.g., include one or multiple of the radio frequency absorbent materials previously described in connection with FIG. 1. A relative permittivity (or dielectric constant) εᵣ of the radio frequency absorber material 36 may be greater than about 3. A loss tangent tan δ of the radio frequency absorber material 36 may be greater than about 0.2. In a more specific, but non-limiting example, the loss tangent tan δ may be greater than about 0.3.

The device 500 of FIG. 5 may be at least partly similar to the device 400 of FIG. 4. Similarly, a radio frequency absorber material 36 may be arranged between the radio frequency chip 2 and the heat sink 22. The radio frequency absorber materials 36 of FIGS. 4 and 5 may differ with regard to relative permittivity εᵣ and thickness. In the example of FIG. 5, a relative permittivity (or dielectric constant) εᵣ of the radio frequency absorber material 36 may be greater than about 5. In a more specific, but non-limiting example, the relative permittivity εᵣ of the radio frequency absorber material 36 may be greater than about 7. The radio frequency absorber material 36 of FIG. 5 may be formed as one single layer having a substantially uniform thickness when measured in the z-direction. In this context, a thickness of the radio frequency absorber material 36 may be greater than about 1 mm. In a more specific, but non-limiting example, the thickness of the radio frequency absorber material 36 may be in a range from about 0.2 mm to about 0.45 mm.

The device 600 of FIG. 6 may be at least partly similar to the devices 400 and 500 of FIGS. 4 and 5, respectively. In the example of FIG. 6, the radio frequency absorber material 36 of FIGS. 4 and 5 may be replaced by a mold compound material 38 arranged between the radio frequency chip 2 and the heat sink 22. In particular, the heat sink 22 may be directly placed on top of the mold compound material 38. In one example, the mold compound material 38 may include one or multiple of the materials previously specified in connection with the encapsulation material 6 of FIG. 1. In further examples, Al₂O₃ fillers may be used within a silicone matrix in order to achieve high relative permittivity values and high thermal conductivity values of the mold compound material 38. Here, thermal conductivity values between about 3 W/mK and about 5 W/mK may be possible.

In the example of FIG. 6, the mold compound material 38 may exemplarily correspond to an overmold material arranged on top of the encapsulation material 6. In further examples, the encapsulation material 6 and the mold compound material 38 may form one single piece. In such cases, the radio frequency chip 2 may be encapsulated in the mold compound material 38. A relative permittivity (or dielectric constant) εᵣ of the mold compound material 38 may be greater than about 2, and a loss tangent tan δ of the mold compound material 38 may be smaller than about 0.1. In the example of FIG. 6, the mold compound material 38 may be formed as one single layer having a substantially uniform thickness when measured in the z-direction. In this context, a thickness of the mold compound material 38 may be greater than about 0.4 mm. In a more specific, but non-limiting example, a thickness of the mold compound material 38 may be greater than about 0.5 mm.

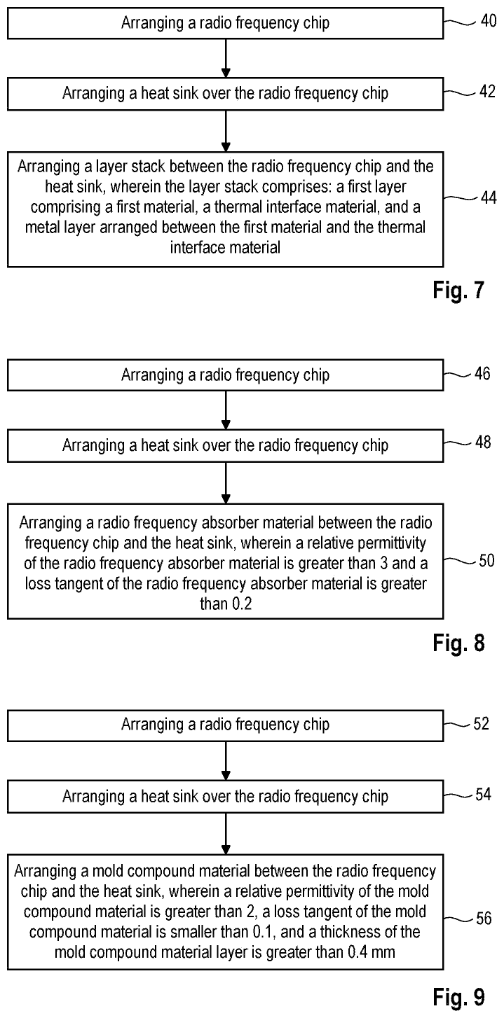

Various methods may be used for manufacturing devices in accordance with the disclosure. FIGS. 7 to 9 illustrate flowcharts of three such example methods. The methods may be read in connection with previously described devices in accordance with the disclosure. The methods of FIGS. 7 to 9 are described in a general manner in order to qualitatively specify aspects of the disclosure. It is understood that the methods may include further aspects. For example, the methods may be extended by any of the aspects described in connection with other examples in accordance with the disclosure.

The method of FIG. 7 may e.g., be used for manufacturing the devices 100 to 300 of FIGS. 1 to 3 including a layer stack 14 arranged between the radio frequency chip 2 and the heat sink 22. At 40, a radio frequency chip may be arranged. At 42, a heat sink may be arranged over the radio frequency chip. At 44, a layer stack may be arranged between the radio frequency chip and the heat sink. The layer stack may include the following: a first layer including a first material, a thermal interface material, and a metal layer arranged between the first material and the thermal interface material.

The method of FIG. 8 may e.g., be used for manufacturing the devices 400 and 500 of FIGS. 4 and 5 including a frequency absorber material 36 arranged between the radio frequency chip 2 and the heat sink 22. At 46, a radio frequency chip may be arranged. At 48, a heat sink may be arranged over the radio frequency chip. At 50, a radio frequency absorber material may be arranged between the radio frequency chip and the heat sink. A relative permittivity of the radio frequency absorber material may be greater than 3, and a loss tangent of the radio frequency absorber material may be greater than 0.2.

The method of FIG. 9 may e.g., be used for manufacturing the device 600 of FIG. 6 including a mold compound material 38 arranged between the radio frequency chip 2 and the heat sink 22. At 52, a radio frequency chip may be arranged. At 54, a heat sink may be arranged over the radio frequency chip. At 56, a mold compound material may be arranged between the radio frequency chip and the heat sink. A relative permittivity of the mold compound material may be greater than 2, a loss tangent of the mold compound material may be smaller than 0.1, and a thickness of the mold compound material layer may be greater than 0.4 mm.

### ASPECTS

In the following, devices in accordance with the disclosure will be explained using aspects.

Aspect 1 is a device, comprising: a radio frequency chip; a heat sink arranged over the radio frequency chip; and a layer stack arranged between the radio frequency chip and the heat sink, wherein the layer stack comprises: a first layer comprising a first material, a thermal interface material, and a metal layer arranged between the first material and the thermal interface material.

Aspect 2 is a device according to Aspect 1, wherein the first material comprises a radio frequency absorber material.

Aspect 3 is a device according to Aspect 1 or 2, wherein the first material is arranged adjacent to the radio frequency chip and the thermal interface material is arranged adjacent to the heat sink.

Aspect 4 is a device according to one of the preceding Aspects, wherein: the first material is configured to mitigate crosstalk between multiple radio frequency channels of the radio frequency chip in order to obtain improved radio frequency isolation between the multiple radio frequency channels, and the thermal interface material is configured to dissipate heat generated by the radio frequency chip.

Aspect 5 is a device according to one of the preceding Aspects, wherein: the first material is configured to mitigate crosstalk between a radio frequency channel of the radio frequency chip and a circuit of a further chip, and the thermal interface material is configured to dissipate heat generated by the radio frequency chip.

Aspect 6 is a device according to one of the preceding Aspects, wherein: a relative permittivity of the first material is greater than 5, and a loss tangent of the first material is greater than 0.1.

Aspect 7 is a device according to Aspect 6, wherein a thickness of the first material is in a range from 0.2 mm to 0.6 mm.

Aspect 8 is a device according to Aspect 6 or 7, wherein the first material comprises at least one of carbon, rubber material, conducting polymer, chiral material, or a polymer matrix including at least one of conducting particles or magnetic particles.

Aspect 9 is a device according to Aspect 1, wherein: a relative permittivity of the first material is greater than 2, a loss tangent of the first material is smaller than 0.1, and a thickness of the first material is in a range from 0.4 mm to 0.8 mm.

Aspect 10 is a device according to Aspect 1, wherein: a relative permittivity of the first material is greater than 5, a loss tangent of the first material is greater than 0.2, and a thickness of the first material is in a range from 0.2 mm to 0.4 mm.

Aspect 11 is a device according to Aspect 9 or 10, wherein the first material comprises a mold compound material.

Aspect 12 is a device according to Aspect 11, wherein the radio frequency chip is encapsulated in the mold compound material.

Aspect 13 is a device according to one of the preceding Aspects, wherein a thickness of the metal layer is greater than two times a skin depth of the metal layer at an operating frequency of the radio frequency chip.

Aspect 14 is a device according to one of the preceding Aspects, wherein: a relative permittivity of the thermal interface material is greater than 5, a loss tangent of the thermal interface material is smaller than 0.1, and a thickness of the thermal interface material is greater than 0.5 mm.

Aspect 15 is a device according to one of the preceding Aspects, wherein the thermal interface material comprises a silicone matrix with inorganic fillers.

Aspect 16 is a device according to one of the preceding Aspects, wherein an operating frequency of the radio frequency chip is greater than 1 GHz.

Aspect 17 is a device according to one of the preceding Aspects, wherein the heat sink comprises a metal part, wherein a thickness of the metal part in a direction perpendicular to a main surface of the radio frequency chip is at least 1 mm.

Aspect 18 is a device, comprising: a radio frequency chip; a heat sink arranged over the radio frequency chip; and a radio frequency absorber material arranged between the radio frequency chip and the heat sink, wherein a relative permittivity of the radio frequency absorber material is greater than 3, and a loss tangent of the radio frequency absorber material is greater than 0.2.

Aspect 19 is a device according to Aspect 18, wherein a thickness of the radio frequency absorber material is greater than 1 mm.

Aspect 20 is a device according to Aspect 18, wherein the relative permittivity of the radio frequency absorber material is greater than 5 and a thickness of the radio frequency absorber material is greater than 0.1 mm.

Aspect 21 is a device according to one of Aspects 18 to 20, wherein the radio frequency chip is arranged over a printed circuit board and a surface of the heat sink does not contact the printed circuit board.

Aspect 22 is a device according to Aspect 21, wherein the heat sink is fully arranged over a top surface of the radio frequency chip facing away from the printed circuit board.

Aspect 23 is a device, comprising: a radio frequency chip; a heat sink arranged over the radio frequency chip; and a mold compound material arranged between the radio frequency chip and the heat sink, wherein a relative permittivity of the mold compound material is greater than 2, a loss tangent of the mold compound material is smaller than 0.1, and a thickness of the mold compound material layer is greater than 0.4 mm.

Aspect 24 is a device according to Aspect 23, wherein the radio frequency chip is encapsulated in the mold compound material.

As employed in this specification, the terms “connected”, “coupled”, “electrically connected”, and/or “electrically coupled” may not necessarily mean that elements must be directly connected or coupled together. Intervening elements may be provided between the “connected”, “coupled”, “electrically connected”, or “electrically coupled” elements.

Further, the word “over” used with regard to e.g., a material layer formed or located “over” a surface of an object may be used herein to mean that the material layer may be located (e.g., formed, deposited, etc.) “directly on”, e.g., in direct contact with, the implied surface. The word “over” used with regard to e.g., a material layer formed or located “over” a surface may also be used herein to mean that the material layer may be located (e.g., formed, deposited, etc.) “indirectly on” the implied surface with e.g., one or multiple additional layers being arranged between the implied surface and the material layer.

Furthermore, to the extent that the terms “having”, “containing”, “including”, “with”, or variants thereof are used in either the detailed description or the claims, such terms are intended to be inclusive in a manner similar to the term “comprising”. That is, as used herein, the terms “having”, “containing”, “including”, “with”, “comprising”, and the like are open-ended terms that indicate the presence of stated elements or features, but do not preclude additional elements or features. The articles “a”, “an”, and “the” are intended to include the plural as well as the singular, unless the context clearly indicates otherwise.

Moreover, the word “example” is used herein to mean serving as an example, instance, or illustration. Any aspect or design described herein as “example” is not necessarily to be construed as advantageous over other aspects or designs. Rather, use of the word example is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or multiple” unless specified otherwise or clear from context to be directed to a singular form. Also, at least one of A and B or the like generally means A or B or both A and B.

Devices and methods for manufacturing devices are described herein. Comments made in connection with a described device may also hold true for a corresponding method and vice versa. For example, if a specific component of a device is described, a corresponding method for manufacturing the device may include an act of providing the component in a suitable manner, even if such act is not explicitly described or illustrated in the figures.

Although the disclosure has been shown and described with respect to one or multiple implementations, equivalent alterations and modifications will occur to others skilled in the art based at least in part upon a reading and understanding of this specification and the annexed drawings. The disclosure includes all such modifications and alterations and is limited only by the concept of the following claims. In particular regard to the various functions performed by the above described components (e.g.,, elements, resources, etc.), the terms used to describe such components are intended to correspond, unless otherwise indicated, to any component which performs the specified function of the described component (e.g.,, that is functionally equivalent), even though not structurally equivalent to the disclosed structure which performs the function in the herein illustrated example implementations of the disclosure. In addition, while a particular feature of the disclosure may have been disclosed with respect to only one of several implementations, such feature may be combined with one or multiple other features of the other implementations as may be desired and advantageous for any given or particular application.

1. A device, comprising:
a radio frequency chip;
a heat sink arranged over the radio frequency chip; and
a layer stack arranged between the radio frequency chip and the heat sink,
wherein the layer stack comprises:
a first layer comprising a first material,
a thermal interface material, and
a metal layer arranged between the first material and the thermal interface material.

2. The device of claim 1, wherein the first material comprises a radio frequency absorber material.

3. The device of claim 1, wherein the first material is arranged adjacent to the radio frequency chip and the thermal interface material is arranged adjacent to the heat sink.

4. The device of claim 1, wherein:
the first material is configured to mitigate crosstalk between multiple radio frequency channels of the radio frequency chip in order to obtain improved radio frequency isolation between the multiple radio frequency channels, and
the thermal interface material is configured to dissipate heat generated by the radio frequency chip.

5. The device of one of the preceding claims claim 1, wherein:
the first material is configured to mitigate crosstalk between a radio frequency channel of the radio frequency chip and a circuit of a further chip, and
the thermal interface material is configured to dissipate heat generated by the radio frequency chip.

6. The device of claim 1, wherein:
a relative permittivity of the first material is greater than 5, and a loss tangent of the first material is greater than 0.1.

7. The device of claim 6, wherein a thickness of the first material is in a range from 0.2 mm to 0.6 mm.

8. The device of claim 6, wherein the first material comprises at least one of carbon, a rubber material, a conducting polymer, a chiral material, or a polymer matrix including at least one of conducting particles or magnetic particles.

9. The device of claim 1, wherein:
a relative permittivity of the first material is greater than 2,
a loss tangent of the first material is smaller than 0.1, and
a thickness of the first material is in a range from 0.4 mm to 0.8 mm.

10. The device of claim 1, wherein:
a relative permittivity of the first material is greater than 5,
a loss tangent of the first material is greater than 0.2, and
a thickness of the first material is in a range from 0.2 mm to 0.4 mm.

11. The device of claim 9, wherein the first material comprises a mold compound material.

12. The device of claim 11, wherein the radio frequency chip is encapsulated in the mold compound material.

13. The device of claim 1, wherein a thickness of the metal layer is greater than two times a skin depth of the metal layer at an operating frequency of the radio frequency chip.

14. The device of claim 1, wherein:
a relative permittivity of the thermal interface material is greater than 5,
a loss tangent of the thermal interface material is smaller than 0.1, and
a thickness of the thermal interface material is greater than 0.5 mm.

15. The device of claim 1, wherein the thermal interface material comprises a silicone matrix with inorganic fillers.

16. The device of claim 1, wherein an operating frequency of the radio frequency chip is greater than 1 GHz.

17. The device of claim 1, wherein
the heat sink comprises a metal part, and
wherein a thickness of the metal part in a direction perpendicular to a main surface of the radio frequency chip is at least 1 mm.

18. A device, comprising:
a radio frequency chip;
a heat sink arranged over the radio frequency chip; and
a radio frequency absorber material arranged between the radio frequency chip and the heat sink,
wherein a relative permittivity of the radio frequency absorber material is greater than 3, and a loss tangent of the radio frequency absorber material is greater than 0.2.

19. The device of claim 18, wherein a thickness of the radio frequency absorber material is greater than 1 mm.

20. The device of claim 18, wherein the relative permittivity of the radio frequency absorber material is greater than 5 and a thickness of the radio frequency absorber material is greater than 0.1 mm.

21. The device of claim 18, wherein the radio frequency chip is arranged over a printed circuit board and a surface of the heat sink does not contact the printed circuit board.

22. The device of claim 21, wherein the heat sink is fully arranged over a top surface of the radio frequency chip facing away from the printed circuit board.

23. A device, comprising:
a radio frequency chip;
a heat sink arranged over the radio frequency chip; and
a mold compound material arranged between the radio frequency chip and the heat sink,
wherein a relative permittivity of the mold compound material is greater than 2, a loss tangent of the mold compound material is smaller than 0.1, and a thickness of the mold compound material layer is greater than 0.4 mm.

24. The device of claim 23, wherein the radio frequency chip is encapsulated in the mold compound material.
